(19) United States
(12) Patent Application Publication
(10) Pub. No.: US 2008/0304241 A1
(43) Pub. Date: Dec. 11, 2008

(54) Electronic Device, a Housing Part, and a Method of Manufacturing a Housing Part

(76) Inventors: Willem Franke Pasveer, Eindhoven (NL); Herbert Lifka, Eindhoven (NL); Martin Ouwerkerk, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 12/097,532

(22) PCT Filed: Dec. 15, 2006
(86) PCT No.: PCT/IB06/54889

§ 371 Date: Jun. 14, 2008

(30) Foreign Application Priority Data
Dec. 22, 2005 (EP) 05112776.9

(51) Int. Cl. H05K 7/00; H05K 3/00

(52) U.S. Cl. 361/735; 29/848

(57) ABSTRACT

The present invention relates to an electronic device (1) which comprises a modular housing (2) comprising a plurality of stacked housing parts (4, 6) that are mechanically interconnected by connection means (8, 10), and which comprises electronic parts (16, 26) having contact portions (30, 32) for providing electrical contact between the parts, a housing part adapted to accommodate an electronic part and having contact members for providing electrical contact between the parts, which contact members comprise conductive tracks (12) provided on a first surface (14), wherein the contact members comprise conductive tracks (18) provided on a second surface (20), the tracks on the second surface of a housing part are electrically connected to the tracks on the first surface of said housing part, and the second surface faces towards the first surface of a next housing part when connected to the housing. The invention further relates to a housing part for assembling a modular housing accommodating electronic parts and to a method of manufacturing such a housing part.

### FIELD OF THE INVENTION

The present invention relates to an electronic device according to the preamble of claim 1.

The present invention also relates to a housing part.

Furthermore the present invention relates to a method of manufacturing a housing part.

### BACKGROUND OF THE INVENTION

An electronic device as described in the first paragraph is known, for example, from the British patent application GB 2371674A, which document discloses an electronic device comprising a lower housing part or substrate, in which a micro-electronic component can be embedded, and an upper housing part. The mechanical connection means for the two housing parts comprise respective pillars and recesses that co-operate to form snap-fit connections holding the housing parts together in a detachable manner.

In a first embodiment, an electrical connection between two housing parts is established by means of a conductive via which is in electrical contact with conductive tracks provided on the exterior surfaces of the upper and lower housing parts.

In a second embodiment, the electrical connection between the two housing parts is formed by conductive surface tracks on both a surface of an upper housing part and a surface of the pillar of said housing part and a ring of conductive elastomer applied to the pillar lip. Contact between the housing parts is established in that the ring is connected to conductive tracks on the lower housing part when the two parts are mechanically joined together.

In a third embodiment, the electrical connection between two housing parts is established by means of four vertical, electrically conductive columns that connect to similar columns provided on an interposed gasket. The columns of the gasket connect to surface tracks provided on the exterior surface of the upper housing part.

A problem with this known electronic device is that the technical measures as disclosed in GB 2371674A do not allow to connect an additional housing part to a stack of assembled housing parts, which connection automatically establishes an electrical connection between said additional housing part and an electronic part or an outermost housing part. The British document does disclose the possibility of stacking a plurality of housing parts by providing recesses on the uppermost surface and pillars at the lowermost surface of each housing part in order to accommodate multiple electronic parts, such as micro-chips, but it does not disclose how to obtain the required electrical connections between all these parts. Moreover, further components are needed in addition to the conductive tracks in order to obtain electrical connections between two housing parts. It will be clear from the above that such further components are a conductive via, a ring of conductive elastomer, and electrically conductive columns, respectively. Another disadvantage is that at least a portion of the electrical contacts is arranged in coherence with the connection means providing the mechanical connection. In the second embodiment described above, for example, a ring of conductive elastomer is arranged around the pillar lip. This means that, if one does not establish a proper mechanical contact, the corresponding electrical connections will not be properly made either.

### SUMMARY OF THE INVENTION

It is an object of the present invention to establish the required electrical connections in a simple and flexible manner when assembling an electronic device as described in the first paragraph.

To achieve this object, an electronic device according to the present invention is characterized in that the contact members comprise conductive tracks provided on a second surface, the tracks on the second surface of a housing part are electrically connected to the tracks on the first surface of said housing part, and the second surface faces towards the first surface of a next housing part when the latter is connected to the housing. When connecting a next housing part, the conductive tracks on the second surface of an outermost housing part make it possible to let these tracks connect with the proper contacts of said additional housing part. When connecting a next housing part from the opposite side, the conductive tracks on the second surface of this next housing part will connect with the proper contacts of an outermost housing part. In this way an electrical connection is made automatically each time a next housing part is connected to another housing part or to a module of assembled housing parts. The connection between the tracks on a second surface and the proper contacts may be achieved either directly, for example when the tracks of a second surface directly contact the tracks on the first surface of a next housing part, or indirectly, for example when the tracks of a second surface contact with contact portions of an electronic part, which portions in their turn contact the surface tracks on the first surface of the next housing part. The present invention thus provides more flexibility with respect to the electrical contacts that are required within an electronic device. According to the present invention, it is not necessary to have an electronic part accommodated in each housing part; electrical signals can still be transferred between the housing parts even if one or more housing parts do not accommodate an electronic part. ‘Parts’ in the preamble of claim 1 ‘for providing electronic contact between the parts’, therefore refer to both the electrical parts and the housing parts of the electronic device.

As conductive surface tracks are relatively easy to apply to a housing part, for example by printing the tracks thereon, the invention provides both a simple and flexible manner of establishing the proper electrical contacts throughout an electric device.

In a preferred embodiment, contact portions of an electronic part contact the tracks on the first surface of the housing part accommodating said electronic part. This provides a simple configuration of the components in the electronic device. An electronic part can be disposed on top of the first surface, its contact portions contacting the proper tracks thereon. Such an assembly of an electronic part and a housing part can be automatically connected to the tracks on the first surface of a next housing part or a next electronic part disposed on said first surface via the surface tracks on the second surface.

It is especially preferred that at least one dummy member accommodated by a housing part is provided, the dummy member comprises contact portions on at least two surfaces, the contact portions on a first surface of the dummy member contact the tracks on the first surface of said housing part, and the contact portions on a second surface of the dummy member contact the tracks on the second surface of a next housing part connected to said housing part. This renders it possible to use identical housing parts, which will always connect properly with the next housing part, throughout the housing. Identical housing parts are advantageous with respect to manufacturability. If a certain housing part for some reason does not accommodate an electronic part, a dummy member can be used, so that the exact location of the second surface of an adjacent housing part, or more precisely the vertical level corresponding to the height of the stack, can be the same for all housing parts. This will be explained in more detail below.

In another preferred embodiment, the conductive tracks on the first surface of a housing part are electrically connected to the conductive tracks on the second surface of said housing part by means of surface tracks provided on at least a third surface connecting the first and the second surface. This embodiment renders it possible to compose the contact members of the housing parts entirely or at least mainly of conductive tracks, which tracks are easier to apply to a housing part than, for example, conductive vias disposed inside a housing part or a ring of conductive elastomer arranged around a protrusion of a housing part as described in the prior art.

In yet another preferred embodiment, the housing has a top side, a bottom side, and sides connecting the top and the bottom side, the connection means comprise a sealing member which extends along the sides connecting the top and the bottom side and has a closed perimeter, and the contact members are substantially arranged at the inside of the sealing member. The sealing member seals the electronic device and protects the contact members and the corresponding electrical contacts therein at least at the sides connecting the top and the bottom side. In order to seal the housing from all sides, it is especially preferred that the housing comprises a top and a bottom housing part, which both comprise a closed exterior surface for sealing the top side and the bottom side of the housing, respectively. The method of sealing the housing and protecting the contact members and electronic parts therein is preferably similar to the method and device as described in the non pre-published European patent application EP 05104048.3. This EP-application is incorporated herein by this reference.

In an advantageous embodiment, conductive tracks are provided at the outside of the housing, the tracks being electrically connected to an electronic part. It is especially preferred that such tracks provide an antenna. The advantage of this embodiment is that there is more space available to dispose the antenna, at least compared with the situation where an antenna is disposed within the housing of the electronic device. This is especially advantageous when the antenna must be tuned to signals with a relatively low frequency. Such antennas generally are difficult to arrange on e.g. a printed circuit board accommodated in the housing owing to a lack of space.

The present invention also relates to a housing part for providing a stacked housing that accommodates electronic parts, the housing part comprising:

connection means for providing a detachable mechanical connection between housing parts;

contact members for providing electrical contact between the parts of a housing, which contact members comprise conductive surface tracks on a first surface and conductive surface tracks on a second surface, wherein the tracks on the first surface are electrically connected to the tracks on the second surface, and the second surface faces away from the first surface.

Such housing parts render it possible to create an electronic device in a simple manner, accommodating the required electronic parts in the housing parts and subsequently interconnecting the housing parts. Given a suitable design, it is even possible to perform these actions manually with no special tools required. Furthermore, it is possible to detach the housing parts of the electronic device thus created and subsequently reconfigure the device, e.g. by changing one of the electronic parts.

It is preferred that conductive tracks on at least a third surface connecting the first and the second surface provide the electrical connection between the tracks on the first and the second surface. This provides a simple manufacturing method for providing the contact members. It is also preferred that the housing part has a substantially circular shape. This is advantageous for reasons of symmetry and renders it possible to form a cylindrical housing. The housing parts are preferably used to compose an electronic device as described above.

Furthermore, the present invention relates to a method of manufacturing a housing part, the method comprising:

injection-molding a part, the part comprising connection means for mechanical connection to similar parts and comprising at least a first surface, a second surface, and a third surface;

providing conductive tracks on the first surface, the second surface, and the third surface.

It is preferred that the step of providing conductive tracks comprises printing of the tracks or applying them by electrochemical deposition. With this embodiment it is especially preferred that conductive tracks are printed on one or more non-conductive foils, the foils are arranged in the mold before injection molding of a housing part for providing the conductive tracks on the first surface, the second surface, and the third surface during injection molding. These methods render it possible to create housing parts by simple manufacturing methods.

### BRIEF DESCRIPTION OF THE DRAWINGS

The invention will be further explained below with reference to the accompanying drawings, in which:

FIGS. 1a and 1b are cross-sectional views of two housing parts before and after their interconnection; and

FIG. 2 is a perspective and partial view of a housing part.

### DETAILED DESCRIPTION OF THE EMBODIMENTS

Like reference numbers refer to like parts in the drawings.

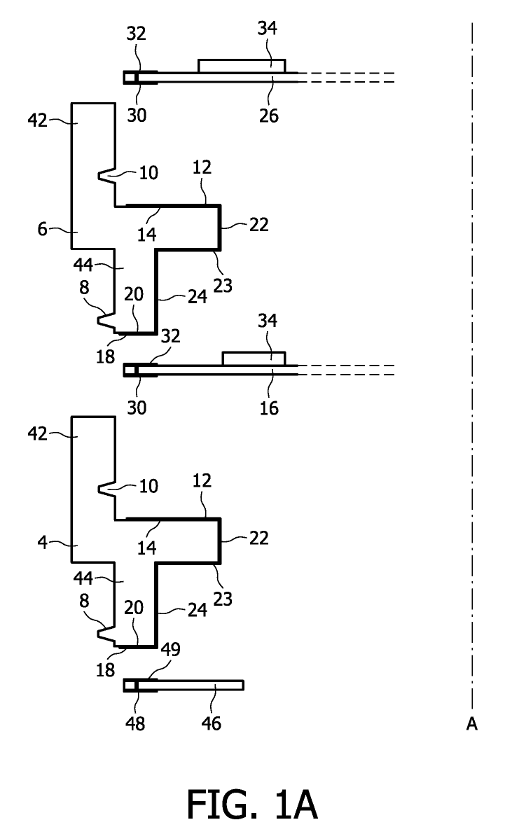

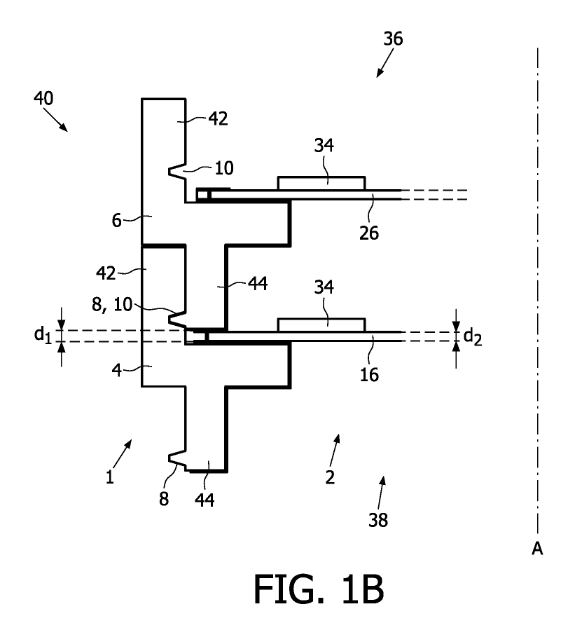

FIGS. 1a and 1b show two housing parts 4, 6 and two electronic parts 16, 26, such as printed circuit boards, before and after these parts were assembled together, respectively. The assembly composes an electronic device 1, wherein the electronic parts 16, 26 are accommodated in a housing 2 (see FIG. 1b). The housing parts and the electronic parts are preferably circularly shaped, while the housing parts 4, 6 are preferably symmetrical with respect to a central axis A. The electronic parts 16, 26 preferably comprise a printed circuit board (PCB), several electronic components 34, such as Integrated Circuits (ICs) or surface mounted devices (SMDs) being mounted on the PCB. It is convenient to use an electronic part that is also circularly shaped. However, it is alternatively possible to use a square component. This will be illustrated in more detail below.

Each housing part 4, 6 comprises contact members providing the electrical interconnections that are required between the housing parts and the electronic parts. The contact members comprise conductive surface tracks 12 provided on a first surface 14. At some distance from this surface 16, conductive surface tracks 18 are provided on a second surface 20. The second surface faces 20 away from the first surface 14 and towards the first surface of a next housing part when assembled in a modular housing. The tracks 12 on the first surface 14 are electrically connected to the tracks 18 on the second surface by means of conductive tracks 22, 23, 24 provided on a third, a fourth and a fifth surface of the housing part, respectively. It is also possible to connect the tracks of the first and the second surface by means of respective conductive tracks provided only on a third surface. For reasons of clarity, the conductive surface tracks and the corresponding surfaces are only indicated by their respective reference numbers in FIG. 1a.

The electronic part 16, 26 preferably comprises contact portions 30, 32 provided on two opposing surfaces. Contact portions of one surface are connected to contact portions of the opposing surface.

When composing the electronic device, first one disposes an electronic part 16 on a housing part 4 while establishing electrical contact between the contact portions 30 of part 16 with the proper conductive surface tracks 12 on the first surface 14. Next one connects to the housing part 4 a second housing part 6 by coupling connection means 8, 10 provided on each housing part for establishing a mechanical connection between the housing parts. The functioning of the connection means 8, 10 will be described in more detail below. Upon connecting the two housing parts, the contact portions 32 of electronic part 16 are electrically connected to the surface tracks 18 on the second surface 20 of the next housing part 6, as is shown in FIG. 1b.

By disposing a second electronic part 26 in the connected housing part 6, again with contact portions 30 contacting the conductive tracks 12 on the first surface 14 of said housing part, one establishes electrical connections between the two electronic parts 16, 26 in the device.

In the situation shown in FIG. 1b, a housing 2 accommodating two electronic parts 16, 26 forms an electronic device 1 having a (circular) top side 36, a (circular) bottom side 38, and (cylindrical) lateral sides that connect the top side 36 and the bottom side 40. Each housing part has a ring-shaped upper part 42 and a ring shaped lower part 44.

Preferably, the connection means 8, 10 comprises a sealing member 8 which comprises a circular protrusion that extends along the sides connecting the top and the bottom side 40 and that has a closed perimeter. The sealing member fits a groove 10 of an adjacent housing part when these parts are interconnected. In this way it is achieved that the housing is sealed at least at the sides connecting the top and the bottom side 40. It is preferred that the housing parts are made from a non-conductive flexible material such as synthetic resin in order to facilitate the coupling of the material. Furthermore, it is preferred that the housing parts comprise guiding means (not shown) to guide the connecting action of two housing parts. Such guiding means may comprise, for example, an inclined edge provided at the upper portion 42 of a housing part.

Starting with the device 1 shown in FIG. 1, it is very easy to expand or modify the device. When coupling a housing part from the top side 38 one can manually connect an additional housing part, aligning the tracks on the second surface of the additional housing part with the contact portions 32 on the electronic part 26. Next one can accommodate a third electronic part in the additional housing part. It is also possible to do this before connecting the additional housing part.

When wanting to connect an additional component from the bottom side 36 one manually connects an additional housing part, which preferably accommodates a third electronic part. The conductive tracks on the second surface of the lowermost housing part 4 are aligned with the contact portions of the third electronic part facing said second surface in this manner.

It should be noted that it is also possible to connect an additional housing part not comprising an electronic part from the bottom side. This may be necessary, for example, if a subsequent additional housing part that is connected from the bottom side of the expanded electronic device comprises an electronic part with electronic components of relatively great height (i.e. in the direction defined by axis A in FIGS. 1a and 1b). There are two options here. First, a housing part having a lower part 44 that extends somewhat further may be used. It will be clear that this further extension substantially equals the height of an electronic part. The conductive tracks on the second surface of such a lowermost housing part will then automatically contact the tracks on the first surface of the next housing part. A disadvantage of this solution is that two kinds of housing parts are to be used within one modular housing. One type has a ‘normal’ lower part 44, whereas the other type has an extended lower part 44. It is accordingly preferred to use a dummy member 46 instead. This dummy member is shown at the bottom of FIG. 1a and preferably has the shape of a ring comprising contact portions 48, 49 similar to the contact portions 30, 32 of the electronic parts.

It will be clear from the above description that the electronic device according to the invention renders it possible to establish every possible route that a certain electronic signal should follow within the device. Re-routing of the signal, for example from a certain location at a circular housing part to another location at a distance 90 degrees away from said housing part on the next housing part, is possible by means of re-routing traces within the electronic parts, as will be explained in more detail below.

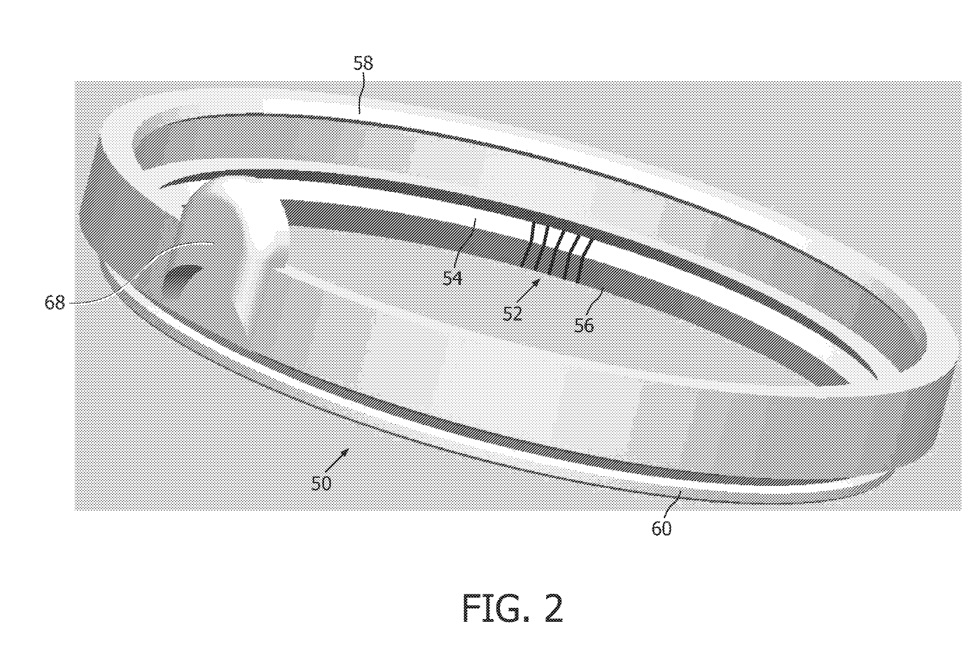

FIG. 2 is a perspective view of a housing part 50. It is clear from this Figure that the contact members of the housing part 50 comprise conductive tracks 52 that run from a first surface 54 to a second surface (not visible) via a third surface 56. The conductive tracks 52 are preferably arranged in substantially parallel tracks. For reasons of clarity, only a small portion of the conductive tracks are displayed in FIG. 2. Two ring-shaped protrusions 58, 60 provided at the upper part and the lower part, respectively, extend along the sides connecting the top and the bottom sides. These protrusions have a closed perimeter and provide the mechanical connection between two housing parts. When connecting two housing parts, two corresponding protrusions hook into each other. This is accordingly somewhat different from the connection means 8, 10 shown in FIGS. 1a and 1b. The shape of the housing part itself also deviates somewhat from the shape shown in FIGS. 1a and 1b.

Furthermore, FIG. 2 shows alignment means 68 comprising a semicircular protrusion at the exterior of the housing part 50, which means couple with the semicircular recess of the alignment means of a next housing part. The alignment means 68 allow a proper alignment between two housing parts as regards the corresponding electrical connections. It is preferred that a housing part comprises similar alignment means at its interior (not visible in FIG. 2), providing a proper alignment of an electronic part that is accommodated by the housing part.

Although not shown in the drawings, it is preferred that the housing comprises a top and a bottom housing part which both have a closed exterior surface. It can be achieved thereby that the housing is also sealed at the top 36 and the bottom 38 of the housing. Together with the sealing for the sides connecting the top 36 and the bottom 40 provided by the connection means 8, 10, 58, 60 of the housing parts, a tight sealing of the entire housing 2 is obtained. Tests have shown that such a housing is completely sealed from water entering the housing when stored in a highly moist environment.

It will be clear that the contact members and the corresponding mechanism for the electrical connections for the outermost housing parts of the device may be different from the situation shown in FIGS. 1 and 1b. This will be the case when such housing parts accommodate special electronic parts such as a solar cell or a battery, or when they do not accommodate any electronic part at all.

A favorable application is one in which an antenna is provided at the exterior side of the housing 2, preferably along the sides connecting the top 36 and the bottom 40. The antenna is passed through the housing wall at some point and connected to one of the conductive tracks or a contact portion. Alternatively, the antenna may be disposed within the housing, for example at the outside of the electronic parts 16, 26. The first option is preferred, however, since in that case longer antennas can be used, which are favorable when tuning to low-frequency signals is required. It is possible to provide the exterior side of the housing with grooves accommodating an outside antenna.

The contact members of a housing part are preferably entirely composed of conductive surface tracks. In order to improve the contacting properties, however, it is possible to apply other components such as small bumps that are provided on the tracks at the proper locations. These bumps preferably comprise gold. The tracks are preferably somewhat widened in those locations where the surface tracks actually contact a next part.

The contact portions of the electronic parts are preferably square portions of gold printed thereon. The contact portions on opposite sides of the electronic part are electrically connected by means of conductive tracks at the inside of the electronic part. This does not automatically mean that a first contact portion on one side is connected to a second contact portion being located on the other side exactly opposite to the first contact portion, since these conductive traces may be used to re-route a certain signal in the electronic device.

Preferably, the housing parts are made from a transparent synthetic resin such as polymethylmethacrylate (PMMA) and polystyrene (PS), which renders it possible to a solar cell as one of the electronic parts within the housing. Such a solar cell is preferably accommodated in an outermost housing part. Furthermore, one can observe all electronic components in this case, which may be advantageous to facilitate the use of status LEDs. Other resins that are preferably used for manufacturing the housing parts are polypropylene (PP) and polycarbonate (PC). Therefore injection molding is the preferred manufacturing technique for the housing parts.

As was noted above, electronic parts preferably have a circular shape, which is more convenient for accommodating them in circular housing parts. However, it also possible to use some kind of square seat in the interior of a housing part, which seat supports a square electronic part. This renders it possible to use the conductive tracks on square surfaces, which is easier than on circular surfaces. It is also possible to accommodate square electronic parts in square housing parts.

The electronic connections in the electronic device may be improved, for example, by designing the housing parts such as to ensure that the space d₁ between the first and the second surface of two adjacent connected housing parts 4, 6 is at most equal to the height d₂ of an electronic part. Preferably, the space d₁ is somewhat smaller than the height d₂. Another option is to construct first and second surfaces that are somewhat resilient with respect to the housing part body. Regarding the materials that are used and the specific construction, it should be realized that the electronic device is preferably applied in environments with a relatively stable temperature, such as a sensor device that is worn on the human body.

The conductive tracks are disposed on the housing parts in that they are consecutively printed on the respective surfaces. Alternatively, tracks may be printed on a non-conductive foil, the foil being glued to the respective surfaces, if necessary in parts. A more advantageous option in this case is to arrange the foil(s) correctly within the mold used for injection molding the housing part. Obviously this is done just before the actual injection molding step. With this option it is possible to apply the conductive tracks coherently with the injection molding step. Other alternatives here are techniques such as electrochemical deposition, lithography, etching, laser activation, metallization, etc. The conductive tracks are preferably made of a copper alloy. Alternatively tracks with gold (alloy) may be provided.

In a preferred embodiment, the electronic device subsequently comprises the following electronic parts; a battery, a transceiver such as a ZigBee 2.45 GHz transceiver, a digital signal processor (DSP) such as a the so-called Coolflux, a Kionix KXM52 accelerometer sensor, a ST M25P20 2 Mbit flash memory, and a photovoltaic cell. With such embodiments the electronic device can be used as a body worn activity monitor.

The electronic device according to the invention may be used, for example, as a UV dosage monitor, since the device can be designed to be very small and is thus easy to carry. Furthermore, it is resistant to moist or sunny environments as was explained above.

When a CMOS90 Coolflux chip is used, the electronic device can function with a clock speed of up to 120 MHz with 8 operations per cycle.

Furthermore, the electronic device according to the invention is very suitable for connection to a docking bay such as, for example, a PC connection or a data cable, which can be achieved in that such a docking bay is provided with appropriate contact members that co-operate with the contact portions of an upper electronic part. Such an assembly of a docking bay and an electronic device can function, for example, as a gateway device for a wireless network of miniature sensor devices. For connection to a docking bay it may be necessary to remove an outermost housing part to get access to the contact portions or the contact members in the electronic device. Alternatively, one can apply special contacts provided at the outside of an outermost housing part, which contacts extend through the housing wall. Such special contacts may also be advantageously used to connect an outside antenna or a battery charger.

It is also possible, however, to establish a wireless contact, for example by means of an infrared coupling. In this case it is necessary that at least part of the housing be made from a transparent synthetic resin, such as PMMA. An additional advantage of using a transparent resin is that status LEDs can be used within the housing, for example to indicate the transfer of data, an on/off status, or the power level of a battery.

It should be noted that the above-mentioned embodiments illustrate rather than limit the invention, and that those skilled in the art will be capable of designing many alternative embodiments without departing from the scope of the invention as defined by the appended claims.

Several technical measures are described independently. One can favorably combine technical measures described herein whenever this gives a beneficial result, as will be clear to those skilled in the art. For example, if gold bumps are provided on the conductive tracks, these bumps can be arranged on widened portions of the tracks.

In the claims, any reference signs placed in parentheses shall not be construed as limiting the claims. The verb “comprise” and its conjugations do not exclude the presence of elements or steps other than those listed in any claim or the specification as a whole. The singular reference of an element does not exclude the plural reference of such elements and vice versa.

1. An electronic device (1) comprising a modular housing (2), which housing comprises a plurality of stacked housing parts (4, 6, 50) that are mechanically interconnected by connection means (8, 10, 58, 60), and comprises electronic parts (16,26) having contact portions (30, 32) for providing electrical contact between the parts, a housing part adapted to accommodate an electronic part and having contact members for providing electrical contact between the parts, which contact members comprise conductive tracks (12) provided on a first surface (14), characterized in that the contact members comprise conductive tracks (18) provided on a second surface (20), the tracks on the second surface of a housing part are electrically connected to the tracks on the first surface of said housing part, and the second surface faces towards the first surface of a next housing part when the latter is connected to the housing (2).

2. An electronic device as claimed in claim 1, characterized in that contact portions (30) of an electronic part (16, 26) contact the tracks (12) on the first surface (14) of the housing part accommodating said electronic part.

3. An electronic device (1) as claimed in claim 1, characterized in that at least one dummy member (46) accommodated by a housing part is provided, the dummy member comprises contact portions (48, 49) on at least two surfaces, the contact portions (48) on a first surface of the dummy member contact the tracks on the first surface of said housing part, and the contact portions (49) on a second surface of the dummy member contact the tracks on the second surface of a next housing part connected to said housing part.

4. An electronic device (1) as claimed in claim 1, characterized in that the conductive tracks (12) on the first surface (14) of a housing part (4, 6, 50) are electrically connected to the conductive tracks (18) on the second surface (20) of said housing part by means of surface tracks (22, 23, 24) provided on at least a third surface (56) connecting the first and the second surface.

5. An electronic device as claimed in claim 1, characterized in that the housing (2) has a top side (36), a bottom side (38), and sides connecting the top and the bottom side (40), the connection means comprise a sealing member (8, 60) which extends along the sides connecting the top and the bottom side and has a closed perimeter, and the contact members are substantially arranged at the inside of the sealing member.

6. An electronic device (1) as claimed in claim 5, characterized in that the housing (2) comprises a top and a bottom housing part, which top housing part and bottom housing part comprise a closed exterior surface for sealing the top side and the bottom side of the housing.

7. An electronic device (1) as claimed in claim 1, characterized in that conductive tracks are provided at the outside of the housing, the tracks being electrically connected to an electronic part (16, 26) or electrically connected to the contact members.

8. An electronic device as claimed in claim 7, characterized in that the tracks provided at the outside of the housing constitute an antenna.

9. A housing part (4,6,50) for assembling a modular housing (2) accommodating electronic parts (16, 26), the housing part comprising:
connection means (8, 10, 58, 60) for providing a detachable mechanical connection between housing parts;
contact members for providing electrical contact between the parts of a housing, which contact members comprise conductive surface tracks (12) on a first surface (14) and conductive surface tracks on a second surface, wherein the tracks at the first surface are electrically connected to the tracks (18) on the second surface (20), and the second surface faces away from the first surface.

10. A housing part (4,6,50) as claimed in claim 9, characterized in that conductive tracks on at least a third surface (56) connecting the first and the second surface provide the electrical connection between the tracks on the first and the second surface.

11. A housing part (4, 6, 50) as claimed in claim 9, characterized in that the housing part has a substantially circular shape.

12. A method of manufacturing a housing part for assembling a modular housing accommodating electronic parts, the method comprising:
injection molding a part, the part comprising connection means for mechanical connection to similar parts and comprising at least a first, a second, and a third surface, the first surface facing away from the second surface and the third surface connecting the fist and the second surface; and
providing conductive tracks on the first surface, the second surface, and the third surface.

13. A method according to claim 12, characterized in that the step of providing conductive tracks comprises printing and/or electrochemical deposition.

14. A method according to claim 13, characterized in that conductive tracks are printed on one or more non-conductive foils, and the foils are arranged in the mold before injection molding of a housing part for providing the conductive tracks on the first surface, the second surface, and the third surface during injection molding.
